(19) United States
(12) Patent Application Publication
(10) Pub. No.: US 2025/0387843 A1
(43) Pub. Date: Dec. 25, 2025

(54) Method for assembling a housing, and associated assembly system and housing

(71) Applicant: THALES, Meudon (FR)

(72) Inventors: Damien CHALAVOUX, VALENCE CEDEX (FR); David BAYLE, Alboussiere (FR); Mathieu JEANNETEAU, VALENCE CEDEX (FR)

(21) Appl. No.: 19/242,303

(22) Filed: Jun. 18, 2025

(30) Foreign Application Priority Data
Jun. 24, 2024 (FR) 2406761

(51) Int. Cl. B23K 1/00; B23K 101/36

(52) U.S. Cl. CPC B23K 1/0008; B23K 2101/36

(57) ABSTRACT

A method for assembling a housing including an electronic board, a solder fillet and a cap, the method including at least the following operations of positioning the electronic board inside a closed enclosure, positioning a solder preform and the cap, the solder preform being interposed between the electronic board and the cap along a stacking direction, injecting a sealing gas until a first pressure of the sealing gas is reached, increasing a temperature to heat the solder preform, the electronic board, the solder preform and the cap being free to move, when the solder preform has reached a first temperature threshold, additionally injecting sealing gas until a second pressure is reached, and decreasing the temperature inside the enclosure.

### REFERENCE TO RELATED APPLICATION

This application is a U.S. non-provisional application claiming the benefit of French Patent Application No. 24 06761 filed on Jun. 24, 2024, the contents of which are incorporated herein by reference in their entirety.

### TECHNICAL FIELD OF THE INVENTION

The present invention relates to a method for assembling a housing, an assembly system and a housing associated with the method.

### BACKGROUND OF THE INVENTION

In order to assemble housings including, for example, precision sensors, it is known to solder together an electronic board including the sensors, and a cap. This is achieved using a solder preform, disposed between the electronic board and the cap. Once assembled, the housing thus formed has to be hermetic. For this, it is necessary for the electronic board, the solder preform and the cap to be aligned, and remain aligned throughout the assembly process.

It is known to assemble the housing under vacuum, possibly by mechanically holding the parts to be assembled. However, vacuum soldering creates additional costs, as well as the risk of cracks in the solder fillet formed after assembly, or in the cap.

It is also known to assemble the housing under a controlled atmosphere, while mechanically holding the parts during assembly, which increases the complexity of the assembly process, as well as its cost. It is also known to close the assembled housing using a plug, then to fill the housing with gas, when passing through a so-called “glove box” enclosure. However, this increases the number of steps to be carried out to assemble the housing and increases the number of parts, as a plug and gasket have to be manufactured and assembled. The assembly process is therefore time-consuming and complex, and additional parts create additional costs.

### SUMMARY OF THE INVENTION

The purpose of the invention is then to provide a solution for assembling a housing quickly and simply.

To this end, one object of the invention is a method for assembling a housing including an electronic board, a solder fillet and a cap, the method including at least the following operations of:
positioning the electronic board inside a closed enclosure, the electronic board including a cavity;
positioning a solder preform and the cap inside the closed enclosure, the solder preform framing the cavity and being interposed between the electronic board and the cap along a stacking direction;
vacuumizing inside of the closed enclosure;
injecting a sealing gas inside the closed enclosure until a first pressure of the sealing gas is reached;
increasing a temperature inside the closed enclosure to heat the solder preform, the electronic board, the solder preform and the cap being free to move;
when the solder preform has reached a first temperature threshold, the first temperature threshold being greater than or equal to a melting temperature of the solder preform, additionally injecting sealing gas into the closed enclosure, until a second pressure of the sealing gas, strictly greater than the first pressure, is reached; and
decreasing the temperature inside the enclosure until the solder preform reaches a temperature strictly less than the melting temperature of the solder preform, the solder preform then forming a solder fillet mechanically connecting the electronic board and the cap, the solder fillet, the electronic board and the cap delimiting an internal space of the housing.

By virtue of the invention, it is not necessary to mechanically hold the parts during assembly. Indeed, suppression of the gas inside the enclosure keeps the cap in place, thus preventing defects such as misalignment of the cap and the electronic board, or the appearance of bubbles or leaks in the solder fillet. These defects are due, for example, to expansion of the gas inside the housing when the solder preform has already melted, which generates a pressure on the cap likely to move it, or generate bubbles or leaks in the solder fillet in the absence of overpressure of gas in the closed enclosure.

By virtue of the invention, the assembly method does not require mechanical means for holding the parts, adding additional parts, and does not require heating the solder preform under vacuum. Assembly is thus simple, inexpensive and reduces the risk of cracks.

According to other advantageous aspects of the invention, the method includes one or more of the following characteristics, considered individually or according to any technically contemplatable combination:
when the solder preform and the cap are positioned, drying the cavity, the drying operation including injecting inert gas at least once into the closed enclosure followed by vacuumizing inside of the closed enclosure; and
injecting an oxidation-reducing gas inside the closed enclosure;
when a pressure of the sealing gas is substantially equal to the second pressure, increasing the temperature inside the closed enclosure so that the solder preform reaches a second temperature threshold,
and wherein decreasing the temperature inside the closed enclosure until the temperature of the solder preform becomes strictly less than the melting temperature of the solder preform is performed when a predetermined amount of time, measured from a time point when the solder preform has reached the second temperature threshold, has elapsed;
the second temperature threshold is within an interval of 20° C. to 50° C. above the melting temperature of the solder preform;
the first pressure is between 0.8 and 1.2 bar, preferably substantially equal to 1 bar and the second pressure is between 1 and 1.5 bar, preferably substantially equal to 1.3 bar;
the sealing gas includes nitrogen and a tracer gas, the tracer gas being helium;
the solder preform is formed of a eutectic alloy;
the electronic board includes a micro electromechanical system, located in the cavity, and following the operation of positioning the solder preform and the cap, the cap covers the microsystem.

The invention also relates to an assembly system including a closed enclosure, means for vacuumizing the closed enclosure, means for injecting gas inside the closed enclosure, means for heating the closed enclosure and electronic control means, the system being configured to implement the method previously described.

The invention also relates to a housing obtained by the method described above.

### BRIEF DESCRIPTION OF THE DRAWINGS

The invention will appear more clearly upon reading the following description, given only by way of non-limiting example, and made with reference to the drawings in which:

FIG. 1 is a diagram of an electronic board, a solder preform and a cap according to the invention;

FIG. 2 is a cross-section view of a housing according to the invention;

FIG. 3 is a diagram of an assembly system according to the invention;

FIG. 4 is a graph showing the change of a temperature of the solder preform and a pressure inside an enclosure over time; and

FIG. 5 is a flowchart of an assembly method according to the invention.

### DETAILED DESCRIPTION OF THE INVENTION

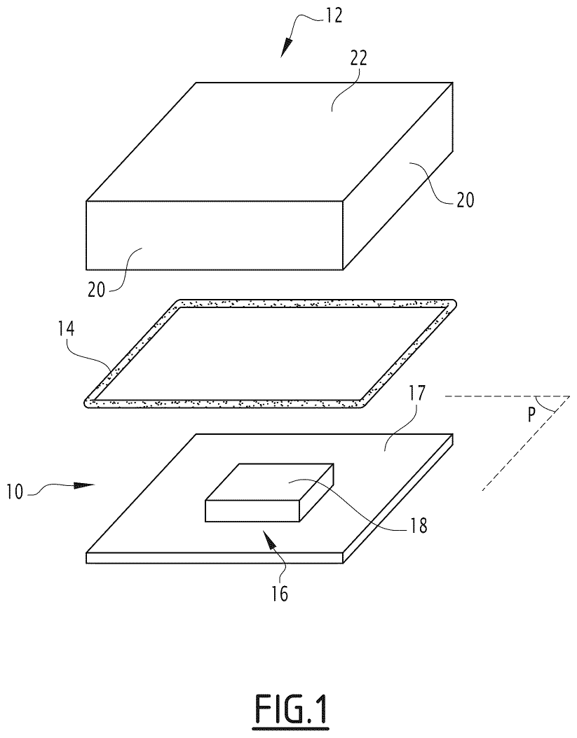

FIG. 1 shows an electronic board 10, a cap 12 and a solder preform 14. The electronic board 10 includes a cavity 16. Advantageously, the electronic board 10 includes a substrate 17, which extends by being substantially parallel to a plane P. Advantageously, the cavity 16 is formed in the substrate 17, in particular, one of the faces of the substrate 17 parallel to the plane P includes the cavity 16. The substrate 17 is advantageously made of ceramic and covered with a film, for example a silver film, not represented. Alternatively, the silver film is deposited only onto one of the faces of the substrate 17, in particular the face of the substrate 17 including the cavity 16.

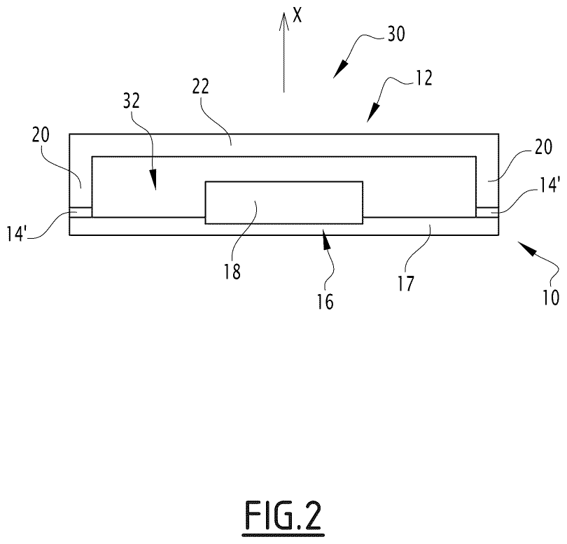

Advantageously, and as represented in FIGS. 1 and 2, the electronic board 10 includes a sensor 18, located in the cavity 16. The sensor 18 is for example a Micro Electromechanical System, or MEMS.

Alternatively, an electronic system, including for example a plurality of electronic chips, is located in the cavity 16.

The cap 12 is advantageously of a metal alloy, for example a nickel-gold alloy. The cap 12 includes at least one, herein four side walls 20, which support a main face 22 of the cap 12. Advantageously, the cap 12 is made as one piece.

The solder preform 14 forms a closed contour, the shape of which follows a shape of the side walls of the cap 12, as projected in the plane P. In the example of FIG. 1, the side walls of the cap 12 form a rectangle as projected in the plane P. Thus, the solder preform 14 is rectangular in shape. The solder preform 14 is advantageously formed of a eutectic metal alloy. By eutectic alloy, it is meant a homogeneous mixture of two or more pure bodies which melts at a constant temperature as a single body. For example, the solder preform 14 is formed of a eutectic alloy of tin-silver, or, alternatively, of gold-tin. The material of the solder preform 14 is advantageously chosen to ensure good wettability with the electronic board 10 on the one hand, and with the cap 12 on the other hand.

For example, in the case where the substrate 17 is covered with silver and the cap 12 is of a nickel-gold alloy, the solder preform 14 is advantageously of a tin-silver alloy.

A housing 30, visible in FIG. 2, is formed by assembling the electronic board 10, the cap 12 and the solder preform 14. When the housing 30 is assembled, the cap 12 is disposed on the electronic board along a stacking direction X perpendicular to the plane P. Advantageously, the cap 12 is disposed on the substrate 17. Advantageously, the cap 12 covers the cavity 16 and the sensor 18.

When the housing 30 is assembled, the solder preform forms a

solder fillet 14′, which mechanically connects the electronic board 10 and the cap 12. Advantageously, the solder fillet 14′ frames the cavity 16. The electronic board 10, the cap 12 and the solder fillet 14′ then form a mechanically integral assembly. The housing 30 is hermetic, that is, a gas present inside the housing 30 cannot escape outside the housing 30, and conversely, a gas outside the housing 30 cannot get inside the housing 30. Thus, in the example of FIGS. 1 and 2, the sensor 18 is insulated from outside. This allows reliable performance of the sensor 18 over time, without interference caused by moisture or pollution of the outside air.

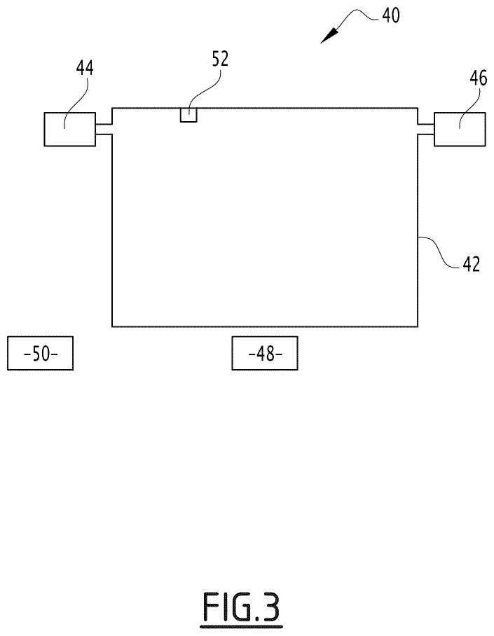

In order to assemble the electronic board 10, the cap 12 and the solder preform 14 to form the housing 30, it is possible to use an assembly system 40, shown in FIG. 3.

The assembly system 40 includes an enclosure 42, the enclosure 42 being a closed enclosure, means 44 for vacuumizing the enclosure 42, means 46 for injecting gas inside the enclosure 42 to inject gas inside the enclosure 42, means 48 for heating the enclosure 42 and electronic control means 50, advantageously connected to the enclosure 42, to the vacuumizing 44, gas injection 46 and heating 48 means. Advantageously, the assembly system 40 also includes a pressure sensor 52, located inside the enclosure 42.

The enclosure 42 is advantageously configured to be tightly closed.

For example, the enclosure 42 and the heating means 48 together form a furnace. The control means 50 are advantageously configured to control the assembly system 40. The control means 50 include for example a computer, including a man-machine interface through which a user controls the different elements of the assembly system 40. The control means 50 advantageously include at least one programmable logic component, such as an FPGA (Field Programmable Gate Array), or an integrated circuit, such as an ASIC (Application Specific Integrated Circuit).

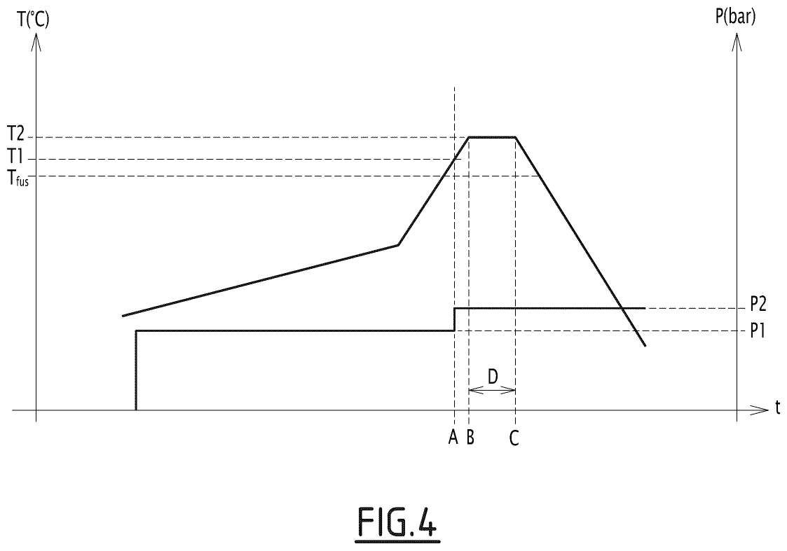

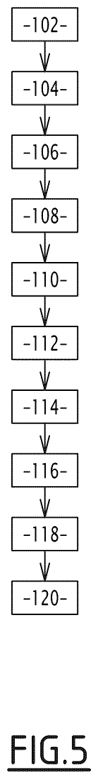

A method for assembling the housing 30 is described with reference to FIGS. 4 and 5. The method includes at least the operations described below.

During a positioning operation 102, the electronic board 10 is disposed inside the enclosure 42. The positioning operation 102 is performed manually, or, advantageously, using an automatic gripping and depositing machine, for example, an articulated arm.

During a positioning operation 104, the solder preform 14 and the cap 12 are positioned inside the closed enclosure 42. In particular, the solder preform 14 is positioned so as to frame the cavity 16 and is interposed between the electronic board 10 and the cap 12 along the stacking direction X.

Advantageously, the solder preform 14 is deposited onto the substrate 17, and the cap 12 is deposited onto the solder preform 14, so that the edge of the side walls 20 is in contact with the solder preform 14 along the stacking direction X.

The positioning operation 104 is advantageously performed by the same automatic gripping and depositing machine as that used during the positioning operation 102. The electronic board 10 and the cap 12 are not connected together tightly, gaps being present between the solder preform 14 and the electronic board 10 on the one hand and the cap 12 on the other hand.

Advantageously, once the positioning operation 104 is performed, a drying operation 106 is carried out. The drying operation 106 includes injecting inert gas at least once, also called neutral gas, into the enclosure 42, for example, via the gas injection means 46, followed by vacuumizing inside of the closed enclosure 42, for example via the vacuumizing means 44. The drying operation 106 thus makes it possible to remove any trace of water on the electronic board 10, including in the cavity 16, on the sensor 18, the cap 12 and the solder preform 14, as well as any residual moisture possibly present inside the enclosure 42.

Advantageously, the drying operation 106 includes several cycles of injecting inert gas followed by vacuumizing inside of the enclosure 42. The inert gas is chosen so that it does not react on contact with the parts 10, 12 and 14 inside the closed enclosure 42, and is for example dinitrogen, more simply called nitrogen hereinafter.

Advantageously, following the drying operation 106, an injection operation 108 is performed. The injection operation 108 is also called the deoxidation operation 108. The deoxidation operation 108 consists in injecting an oxidation-reducing gas inside the enclosure 42.

The deoxidation operation 108 is implemented for example by the gas injection means 46. The oxidation-reducing gas is for example gas-phase formic acid. The deoxidation operation 108 makes it possible to remove any oxide layer present on the surface of the electronic board 10, the solder preform 14 and the cap 12.

Advantageously, once the deoxidation operation 108 is performed, a vacuumizing operation 110 is performed. The vacuumizing operation 110 is advantageously implemented by the vacuumizing means 44, and makes it possible to discharge gases present inside the enclosure 42. For example, the vacuuming operation 110 makes it possible to discharge the reduction-oxidation gas, or redox gas, and the oxidation residues formed in the deoxidation operation 108.

Once the vacuumizing operation 110 is performed, an operation of injecting 112 a sealing gas inside the enclosure 42 is performed. Injecting sealing gas is carried out until a first pressure P1 of sealing gas is reached. In other words, sealing gas is injected into the enclosure 42 as long as a pressure P inside the enclosure 42 is less than or equal to the first pressure P1. The first pressure P1 is for example between 0.8and 1.2 bar, preferably substantially equal to 1 bar. By substantially equal to a quantity, it is meant equal to this quantity plus or minus 1%.

The operation of injecting 112 the sealing gas is advantageously implemented by the gas injection means 46, and the pressure P inside the enclosure 42 is advantageously measured by the pressure sensor 52. According to one example, the sealing gas includes a neutral gas, such as nitrogen, and a tracer gas, for example helium.

When the pressure P inside the enclosure 42 is substantially equal to the first pressure P1, an operation 114 of increasing a temperature inside the closed enclosure 42, also called heating operation 114, is performed, in order to heat the solder preform 14, the temperature T of which increases. The heating operation 114 is advantageously carried out by the heating means 48.

Advantageously, the temperature T of the solder preform 14 is not measured directly, but is for example determined indirectly, by measuring the temperature of the substrate 17. In this case, calibration is carried out prior to assembly to correlate the temperature of the electronic board 10, in particular of the substrate 17, with the temperature T of the solder preform 14.

During operations 106 to 114, the electronic board 10, the cap 12 and the solder preform 14 are not mechanically held. In other words, the electronic board 10, the cap 12 and the solder preform 14 are free to move. In practice, during operations 106 to 114, injection gas and vacuumizing inside of the enclosure 42 are sufficiently gradual to not cause a displacement of one of the parts 10, 12 or 14.

When the solder preform 14 has reached a first temperature threshold T1, an additional operation of injecting 116 sealing gas into the enclosure 42 is performed, until a second pressure P2 of the sealing gas is reached inside the closed enclosure 42, as represented at the time instant A in FIG. 4.

The first temperature threshold T1 is greater than or equal to a melting temperature Trus of the solder preform 14. In the example of FIG. 4, the first temperature threshold T1 is chosen greater than the melting temperature Trus of the solder preform 14.

Thus, when the solder preform 14 has a temperature equal to the first temperature threshold T1, the solder preform 14 is entirely in the liquid state. It then forms a gas-tight barrier. The sealing gas inside a space 32 delimited by the electronic board 10, the solder preform 14 in the liquid state and the cap 12 is therefore contained therein. The space 32 is called the internal space of the housing 30.

Advantageously, the additional injection operation 116 is performed by the gas injection means 46. Advantageously, the second pressure P2 is between 1 and 1.5 bar and is preferably substantially equal to 1.3 bar.

Advantageously, when the pressure P of the gas inside the enclosure 42 is substantially equal to the second pressure P2, an operation of increasing 118 the temperature inside the enclosure 42 takes place, so that the solder preform 14 reaches a second temperature threshold T2, as visible at the time instant B in FIG. 4. The second temperature threshold T2 is advantageously strictly greater than the first temperature threshold T1. The second temperature threshold T2 is for example within an interval of 20° C. to 50° C. above the melting temperature T_{fus} of the solder preform 14. The second temperature threshold T2 is advantageously chosen in order to optimize diffusion of the atoms forming the alloy of the solder preform 14, in the electronic board 10 and in the cap 12, and thus improve the strength of the solder.

Increasing the pressure P up to the second pressure P2 advantageously makes it possible to press the cap 12 against the electronic board 10, and to prevent an untimely movement of the cap 12, as well as the formation of bubbles in the solder preform 14, now liquid. The untimely movements of the cap 12 are for, example, caused by expansion of the sealing gas in the internal space 32, expansion being caused by the temperature increase to heat the solder preform 14 from the first temperature threshold T1 to the second temperature threshold T2. Expansion of the gases may also take place without the need to heat the solder preform 14 to the second temperature threshold T2, and may be caused by the sealing gas in the internal space 32 reaching the temperature T1 only after the solder preform 14 has reached this temperature and has gone into the liquid state.

Advantageously, when the solder preform 14 reaches the second temperature threshold T2, its temperature T is maintained constant and substantially equal to the second temperature threshold T2 for a predetermined amount of time D, measured from the time point when the solder preform 14 has reached the second temperature threshold T2. When the amount of time D has elapsed, a temperature decrease operation 120 is performed, as may be seen at the time instant C in FIG. 4.

During the temperature decrease operation 120, the temperature inside the enclosure 42 decreases. Thus, the temperature T of the solder preform 14, which is in the liquid state, also decreases. The temperature inside the enclosure 42 decreases until the temperature T of the solder preform 14 becomes strictly less than the melting temperature T_{fus} of the solder preform 14. The solder preform 14, which was in the liquid state, solidifies and forms a solder fillet 14′, mechanically connecting the electronic board 10 and the cap 12. The housing 30 is thus formed.

The temperature decrease operation 120 is implemented, for example, by the heating means 48, which stop heating inside of the enclosure 42.

Advantageously, the temperature continues to decrease until a temperature in the order of 20° C. is reached, which allows the housing 30 to be handled with no risk of burning.

Thus, the assembly method described above makes it possible to obtain the housing 30. The solder fillet 14′, the electronic board 10 and the cap 12 delimit the internal space 32 of the housing 30, which is hermetically insulated from outside.

In an alternative, not represented, the operation of increasing 118 the temperature is not carried out, and the operation of decreasing 120 the temperature is performed directly after the operation of additionally injecting 116 sealing gas, advantageously after a predetermined amount of time, measured from the time point when the pressure P in the enclosure 42 is equal to the second pressure threshold P2 is reached, has elapsed.

Any characteristic described for an embodiment or alternative in the foregoing may be implemented for the other embodiments and alternatives described above, as far as technically feasible.

1. A method for assembling a housing comprising an electronic board, a solder fillet and a cap, the method comprising:
positioning the electronic board inside a closed enclosure, the electronic board comprising a cavity;
positioning a solder preform and the cap inside the closed enclosure, the solder preform framing the cavity and being interposed between the electronic board and the cap along a stacking direction;
vacuumizing inside of the closed enclosure;
injecting a sealing gas into the closed enclosure until a first pressure of the sealing gas is reached;
increasing a temperature inside the closed enclosure to heat the solder preform, wherein the electronic board, the solder preform and the cap are free to move;
when the solder preform has reached a first temperature threshold, the first temperature threshold being greater than or equal to a melting temperature of the solder preform, further injecting sealing gas into the closed enclosure, until a second pressure of the sealing gas, strictly greater than the first pressure, is reached; and
decreasing the temperature inside the enclosure until the solder preform reaches a temperature strictly less than the melting temperature of the solder preform, the solder preform then forming a solder fillet mechanically connecting the electronic board and the cap, wherein the solder fillet, the electronic board and the cap delimit an internal space of the housing.

2. The method according to claim 1, further comprising:
when the solder preform and the cap are positioned, drying the cavity comprising injecting inert gas at least once into the closed enclosure followed by vacuumizing inside of the closed enclosure; and
injecting a reduction-oxidation gas inside the closed enclosure.

3. The method according to claim 1, further comprising, when a pressure of the sealing gas is substantially equal to the second pressure, increasing the temperature inside the closed enclosure so that the solder preform reaches a second temperature threshold, and wherein said decreasing the temperature is performed when a predetermined amount of time, measured from a time point when the solder preform has reached the second temperature threshold, has elapsed.

4. The method according to claim 3, wherein the second temperature threshold is within an interval of 20° C. to 50° C. above the melting temperature of the solder preform.

5. The method according to claim 1, wherein the first pressure is between 0.8 and 1.2 bar, and the second pressure is between 1 and 1.5bar.

6. The method according to claim 1, wherein the first pressure is substantially equal to 1 bar, and the second pressure is substantially equal to 1.3 bar.

7. The method according to claim 1, wherein the sealing gas comprises nitrogen and a tracer gas.

8. The method according to claim 7, wherein the tracer gas is helium.

9. The method according to claim 1, wherein the solder preform is formed of a eutectic alloy.

10. The method according to claim 1, wherein the electronic board comprises a micro electromechanical system, located in the cavity, and wherein following said positioning the solder preform and the cap, the cap covers the microsystem.

11. An assembly system comprising:
a closed enclosure;
a vacuumizer vacuumizing said closed enclosure;
an injector injecting gas inside said closed enclosure;
a heater heating said closed enclosure; and
an electronic controller implementing the method according to claim 1.
